(19) United States
(12) Patent Application Publication
(10) Pub. No.: US 2017/0162831 A1
(43) Pub. Date: Jun. 8, 2017

(54) METHOD FOR MANUFACTURING ORGANIC EL DISPLAY PANEL AND SYSTEM FOR MANUFACTURING ORGANIC EL DISPLAY PANEL

(71) Applicant: JOLED INC., Tokyo (JP)

(72) Inventor: Toyoji ITO, Tokyo (JP)

(73) Assignee: JOLED INC., Tokyo (JP)

(21) Appl. No.: 14/906,599

(22) PCT Filed: Apr. 17, 2015
(86) PCT No.: PCT/JP2015/002126

§ 371 Date: Jan. 21, 2016

(30) Foreign Application Priority Data
Apr. 22, 2014 (JP) 2014-088586

(51) Int. Cl. H01L 51/56; H01L 51/50; F26B 11/18; B08B 7/00; B08B 5/00; H01L 51/00; B08B 3/04

(52) U.S. Cl. CPC H01L 51/56; H01L 51/0005; H01L 51/5012; B08B 3/04; B08B 7/0035; B08B 5/00; F26B 11/18

(57) ABSTRACT

A method for manufacturing an organic EL display panel through a printing process of applying, to a board in a first orientation, a raw material liquid for forming at least one of light-emission contribution layers including a light-emission layer, the first orientation being an orientation of the board in which a printing surface faces upward and is held in a horizontal direction. The method includes: a wet cleaning process of cleaning the board; and a first rotation process of rotating the board from a second orientation to the first orientation after the wet cleaning process, the second orientation being an orientation of the board in which the printing surface is tilted at an angle with respect to the printing surface in the first orientation, the angle being selected from a range from 90 to 270 degrees inclusive. The printing process is performed after the first rotation process.

### TECHNICAL FIELD

The present disclosure relates to a method for manufacturing an organic electroluminescent (EL) display panel and a system for manufacturing an organic EL display panel, and relates in particular to a method for manufacturing an organic EL display panel and a system for manufacturing an organic EL display panel for which a printing technique is adopted.

### BACKGROUND ART

Patent Literature (PTL) 1 discloses a method of manufacturing an organic EL display panel using a technique of applying a raw material liquid (functional liquid) between banks (partitions) disposed on a board.

### CITATION LIST

### Patent Literature

### [PTL 1]

[PTL 1] Japanese Unexamined Patent Application Publication No. 2006-113423

### SUMMARY OF INVENTION

### Technical Problem

The present disclosure provides a method for manufacturing an organic EL display panel and a system for manufacturing an organic EL display panel which reduce the possibility of a contaminant becoming stuck to a board before a printing process.

### Solution to Problem

To achieve the above object, a method for manufacturing an organic EL display panel is a method for manufacturing an organic electroluminescent (EL) display panel through a printing process of applying, to a printing surface of a board in a first orientation, a raw material liquid for forming at least one of light-emission contribution layers including a light-emission layer, the printing surface being one surface of the board, the first orientation being an orientation of the board in which the printing surface faces upward and is held in a horizontal direction, the method including: a wet cleaning process of cleaning the board using a liquid; and a first rotation process of rotating the board from a second orientation to the first orientation after the wet cleaning process, the second orientation being an orientation of the board in which the printing surface is tilted at an angle with respect to the printing surface in the first orientation, the angle being selected from a range from 90 degrees to 270 degrees inclusive, wherein the printing process is performed after the first rotation process.

### Advantageous Effects of Invention

The present disclosure makes it possible to prevent, to the extent possible, a contaminant from becoming stuck to a board before a printing process. This makes it possible to prevent absorption and so on of the raw material liquid by a contaminant stuck to the printing surface of the board, and to improve the manufacturing yield of an organic EL display panel.

### BRIEF DESCRIPTION OF DRAWINGS

FIG. 1 is a perspective view schematically illustrating a board during manufacturing of an organic EL display panel.

FIG. 2 is a perspective view of a television which includes an organic EL display panel,

FIG. 3 is a schematic view of a system for manufacturing an organic EL display panel.

FIG. 4 is a side view illustrating a board in a first orientation.

FIG. 5 is a side view illustrating a board in a second orientation as the lowest selectable limit.

FIG. 6 is a side view illustrating a board in a second orientation as the highest selectable limit.

FIG. 7 is a flow chart illustrating a method for manufacturing an organic EL display panel.

FIG. 8 is a flow chart illustrating a variation of a method for manufacturing an organic EL display panel.

### DESCRIPTION OF EMBODIMENTS

### Embodiment 1

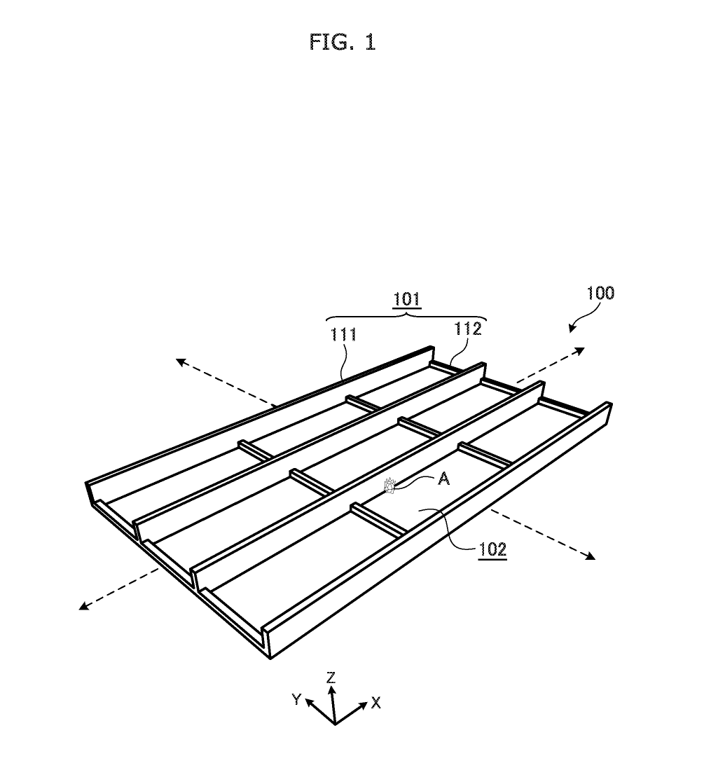

FIG. 1 is a perspective view schematically illustrating a board during manufacturing of an organic EL display panel.

A board 100 illustrated in FIG. 1 is a part of a board 100 after a wet cleaning process and before a printing process. On a printing surface (the surface on the positive side of the Z-axis direction in the drawings) of the board 100 before the printing process, banks (partitions) 101 are disposed in a lattice pattern. The banks 101 include longitudinal banks 111 extending in the longitudinal direction

(X-axis direction in the drawings) and lateral banks 112 extending in the lateral direction (Y-axis direction in the drawings). FIG. 1 shows, for the purpose of illustration, a contaminant A stuck to the board 100 at some stage between the wet cleaning process and the printing process.

The inventor has discovered that when a printing process is performed to apply a raw material liquid (that is, ink) containing an organic EL material for forming, for example, a light-emission layer to the board 100 to which the contaminant A is accidentally stuck, the luminance of a light-emitting pixel 102 in which the contaminant A is present and the luminance of a light-emitting pixel 102 applied with a raw material liquid in contact with the raw material liquid applied to the contaminant-present light-emitting pixel 102 result in being higher than the luminance of a light-emitting pixel 102 in which the contaminant A is absent. The inventor has also discovered that even when a printing process is performed to apply raw material liquids for forming an electron injection layer, an electron transport layer, a hole transport layer, a hole injection layer, and other interlayers, a defect occurs in the manufactured organic EL display panel due to the contaminant A.

The inventor has discovered that a defect occurs not only in the light-emitting pixel 102 to which the contaminant A is stuck but also along a longitudinal bank 111 in the form of a stripe, especially with an organic EL display panel having line banks as illustrated in FIG. 1, that is, an organic EL display panel in which the longitudinal banks 111 linearly extending in the longitudinal direction have a height higher than the height of the lateral banks 112, and light-emitting pixels 102 disposed along the same longitudinal bank 111 are each applied with a raw material liquid which comes in contact with a raw material liquid applied to the other light-emitting pixels 102 disposed along the same longitudinal bank 111.

The present disclosure is based on the above-described new findings. Hereinafter, an embodiment will be described with reference to the drawings as necessary. Note, however, that detailed descriptions may be omitted where unnecessary. For example, detailed descriptions of well-known aspects or repetitive descriptions of essentially similar configurations may be omitted. This is to make the following description easier for those skilled in the art to understand and avoid redundancy.

Note that the inventor provides the accompanying drawings and the following description, not to limit the scope of the claims, but to aid those skilled in the art to adequately understand the present disclosure.

### Embodiment

### [Outline of Organic EL Display Panel]

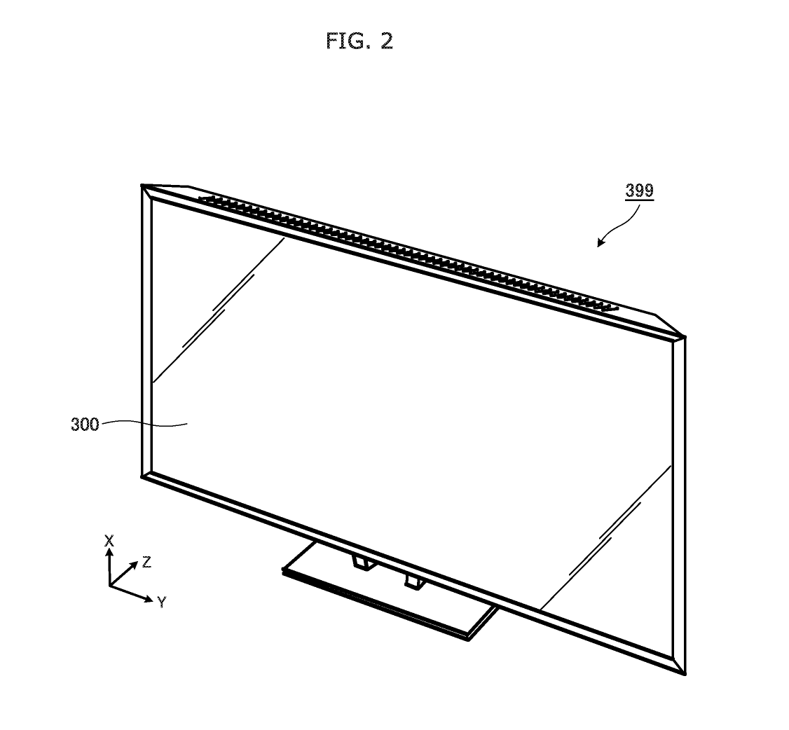

An organic EL display panel 300 is, as illustrated in FIG. 2 for example, an apparatus that displays videos, images, characters, and so on, and is a display apparatus manufactured from the board 100 as illustrated in FIG. 1. For example, the organic EL display panel 300 is built into a television 399 which outputs videos obtained from received broadcast waves and the like. The organic EL display panel 300 includes, as light-emitting elements, organic electroluminescent (EL) diodes that are light-emitting diodes each including a luminescent layer formed using an organic EL material.

The present disclosure describes the case of forming, using a printing method, at least one of light-emission contribution layers interposed between a cathode and an anode and contributing to the light emission performed by light-emitting pixels 102 of the organic EL display panel 300. Examples of the light-emission contribution layers include an electron injection layer, an electron transport layer, a light-emission layer, a hole transport layer, a hole injection layer, and other interlayers.

### [System for Manufacturing Organic EL Display Panel]

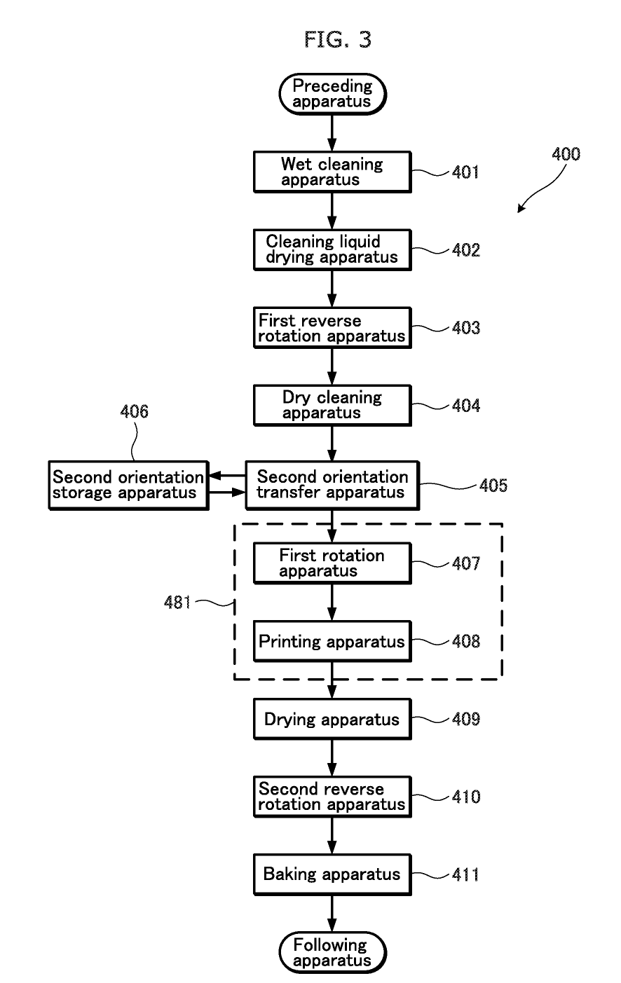

FIG. 3 is a schematic view of a system for manufacturing an organic EL display panel.

As illustrated in FIG. 3, a manufacturing system 400 is a system constituting a part of a production line where a plurality of equipment are sequentially connected via a conveyor. The manufacturing system 400 itself has a production line, too. The manufacturing system 400 includes, from the upstream of the production line, a wet cleaning apparatus 401, a first rotation apparatus 407, and a printing apparatus 408. In the present embodiment, the manufacturing system 400 further includes a first reverse rotation apparatus 403, a dry cleaning apparatus 404, a second orientation transfer apparatus 405, a second orientation storage apparatus 406, a drying apparatus 409, a second reverse rotation apparatus 410, and a baking apparatus 411.

The wet cleaning apparatus 401 is an apparatus that cleans the board 100, especially the printing surface of the board 100, using a liquid such as water. In the present embodiment, the wet cleaning apparatus 401 cleans the board 100 by spraying a liquid to at least the printing surface of the board 100 in a first orientation.

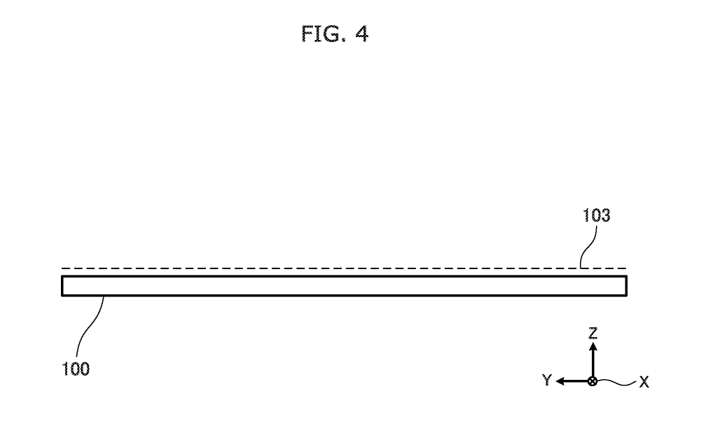

Here, the first orientation refers to an orientation of the board 100 as illustrated in FIG. 4 in which a printing surface 103 (virtually illustrated by dashed lines in the drawings) that is one surface of the board 100 having a flat plate shape (for example, a glass board) faces upward (the positive orientation in the Z-axis direction (vertical direction) in the drawings) and the printing surface 103 is parallel to the horizontal direction (the XY plane in the drawings). Note that the term “horizontal” is used as a concept including not only the perfect horizontal but also a certain level of error. A certain level of error refers to a level of error that enables the printing process to be performed on the board 100 by applying the raw material liquid, and a warp and distortion of the board 100 are also acceptable.

Note that the wet cleaning apparatus 401 is not limited to a spray cleaning apparatus, and may be an immersion cleaning apparatus that cleans the board 100 by immersing the board 100 in a liquid. Furthermore, the orientation of the board 100 during cleaning is not limited to the first orientation.

The first reverse rotation apparatus 403 is an apparatus that rotates the board 100 to a second orientation (reverse rotation). In the present embodiment, the first reverse rotation apparatus 403 rotates the board 100 which has been cleaned by the wet cleaning apparatus 401, from the first orientation to the second orientation (reverse rotation).

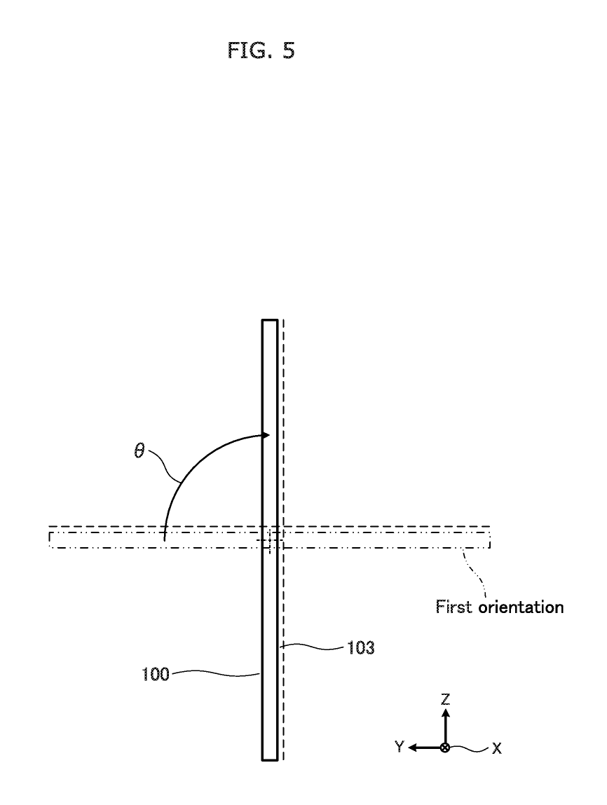

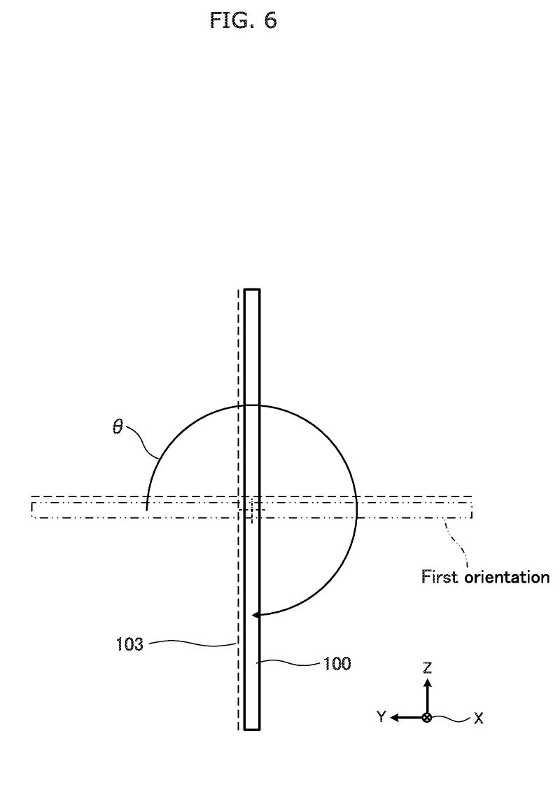

Here, the second orientation is an orientation of the board 100 after being rotated from the first orientation about the rotation axis included in the horizontal plane, in a manner that the printing surface is tilted at an angle selected from a range from 90 degrees (see FIGS. 5) to 270 degrees (see FIG. 6) inclusive, with respect to the printing surface in the first orientation. Examples of the second orientation include: an orientation of the board 100 in which the printing surface 103 faces downward and is parallel to the horizontal direction, that is, an orientation of the board 100 after being rotated 180 degrees from the first orientation; an orientation of the board 100 in which the printing surface 103 faces downward and is tilted at 45 degrees with respect to the first orientation; and an orientation of the board 100 in which the board 100 stands in the vertical direction as illustrated in FIG. 5 and FIG. 6.

Note that in the case where the wet cleaning apparatus 401 has cleaned the board 100 in the second orientation, the first reverse rotation apparatus 403 may be unnecessary.

In the present embodiment, the first reverse rotation apparatus 403 is provided downstream of the cleaning liquid drying apparatus 402. The cleaning liquid drying apparatus 402 is an apparatus that dries the board 100 which has been wet by the wet cleaning apparatus 401, and examples of the cleaning liquid drying apparatus 402 include an air knife. Note that the first reverse rotation apparatus 403 may be provided upstream of the cleaning liquid drying apparatus 402.

The dry cleaning apparatus 404 is an apparatus that removes, using light, gas, plasma, or the like, residues which may remain in a small amount on the surface of the board 100 dried by the cleaning liquid drying apparatus 402.

The second orientation transfer apparatus 405 is an apparatus that transfers the board 100 in the second orientation between the wet cleaning apparatus 401 and the printing apparatus 408. Although FIG. 3 illustrates the second orientation transfer apparatus 405 only between the dry cleaning apparatus 404 and the first rotation apparatus 407, such is a representative illustration, and any apparatus that transfers the board 100 in the second orientation between any apparatuses is the second orientation transfer apparatus 405.

The second orientation storage apparatus 406 is an apparatus that stores the board 100 in the second orientation between the wet cleaning apparatus 401 and the printing apparatus 408. Although the second orientation storage apparatus 406 in FIG. 3 is branched from the main line of the manufacturing system 400, the second orientation storage apparatus 406 may be provided in the main line. Moreover, the second orientation storage apparatus 406 may be provided not only between the wet cleaning apparatus 401 and the printing apparatus 408, but may also be branched to, or provided in the main line at, a position upstream of an apparatus that bottlenecks the manufacturing system 400, for example,

The first rotation apparatus 407 is an apparatus that rotates the board 100 from the second orientation to the first orientation (rotation) between the wet cleaning apparatus 401 and the printing apparatus 408.

Here, the first reverse rotation apparatus 403 and the first rotation apparatus 407 are described as apparatuses that rotate the board 100 about the rotation axis extending in the horizontal direction. However, the first reverse rotation apparatus 403 and the first rotation apparatus 407 may be apparatuses having the same function. Furthermore, the terms “rotation” and “reverse rotation” are used in the following manner: a change in the orientation of the board 100 from the second orientation to the first orientation is referred to as “rotation”, and a change in the orientation of the board 100 from the first orientation to the second orientation is referred to as “reverse rotation”. That is to say, the terms “rotation” and “reverse rotation” are not used to limit the rotation direction of the board 100.

The printing apparatus 408 is an apparatus that applies, to the printing surface 103 of the board 100 in the first orientation, the raw material liquid for forming at least one of light-emission contribution layers.

The printing apparatus 408 according to the present embodiment is an apparatus that applies, between the banks 101 of the board 100, a raw material liquid containing a material for forming an interlayer. Examples of the printing apparatus 408 include an apparatus which applies the raw material liquid using the jet dispensing method. In the present embodiment, the printing apparatus 408 is an apparatus that includes a head having multiple discharge holes arranged in a line or in a narrow band-like region. The head can control discharge of the raw material liquid from each of the discharge holes. Such a printing apparatus 408 can apply any given type of raw material liquid to any given position of the board 100 by moving the head and the board 100 relative to each other.

Note that in the present embodiment, the first rotation apparatus 407 is provided immediately before the printing apparatus 408. Here, “provided immediately before” means that there is no apparatus (except for the transfer apparatus) related to the manufacturing of the organic EL display panel 300 between the first rotation apparatus 407 and the printing apparatus 408.

Furthermore, in the present embodiment, the first rotation apparatus 407 and the printing apparatus 408 are included in a single chamber 481. This prevents, to the extent possible, the contaminant from becoming stuck to the board 100 in the first orientation.

The drying apparatus 409 is an apparatus that dries the raw material liquid printed on the board 100 by the printing apparatus 408. For example, the drying apparatus 409 is a furnace that raises the temperature of the board 100 to a temperature higher than the atmospheric temperature.

The second reverse rotation apparatus 410 is an apparatus that is provided downstream of the printing apparatus 408 and rotates the board 100 from the first orientation to the second orientation. Note that the first reverse rotation apparatus 403 and the second reverse rotation apparatus 410 may be of the same type or different types of apparatuses.

The baking apparatus 411 is an apparatus that processes the board 100 rotated to the second orientation by the second reverse rotation apparatus 410, at a temperature higher than the temperature used by the drying apparatus 409, with the second orientation maintained.

Such a manufacturing system 400 as described above makes it possible to inhibit, to the extent possible, a contaminant from becoming stuck to the printing surface 103 that is a surface of the board 100 on which a light-emission contribution layer is to be formed.

### [Method for Manufacturing Organic EL Display Panel]

Next, a method for manufacturing the organic EL display panel 300 will be described.

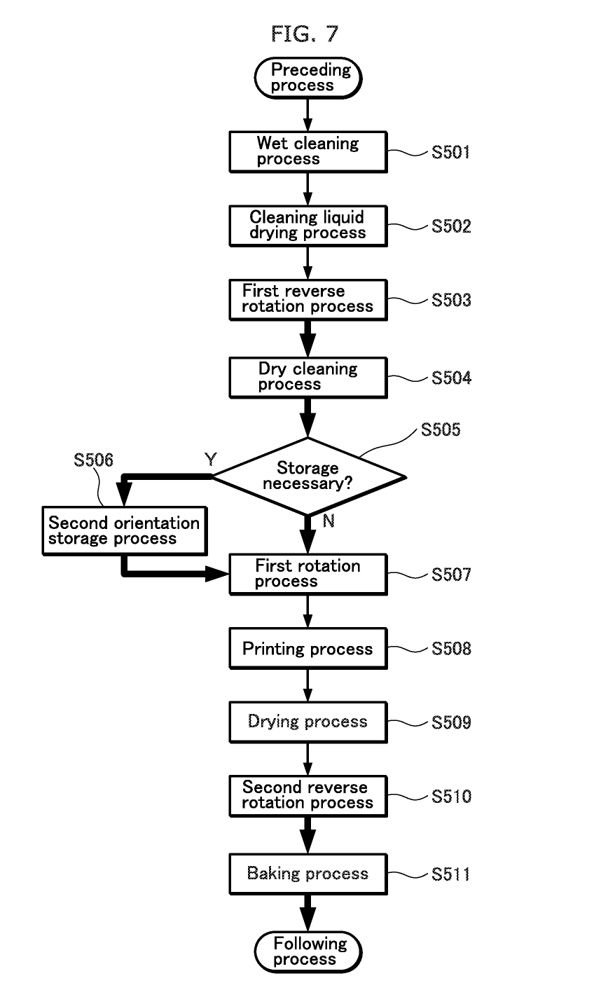

FIG. 7 is a flow chart illustrating a method for manufacturing an organic EL display panel.

First, by the wet cleaning apparatus 401, the printing surface 103 of the board 100 on which the banks 101 and so on have been formed in the preceding process is cleaned using a liquid such as water (wet cleaning process S501). In the wet cleaning process (S501) according to the present embodiment, the board 100 is cleaned in the first orientation.

Next, the board 100 which has been wet in the wet cleaning process (S501) is dried by the cleaning liquid drying apparatus 402 (cleaning liquid drying process S502).

Next, the board 100 is rotated to the second orientation (reverse rotation) by the first reverse rotation apparatus 403 (first reverse rotation process S503). Note that the first reverse rotation process (S503) may be performed before the cleaning liquid drying process (S502).

Next, the board 100 is transferred by the second orientation transfer apparatus 405 with the second orientation maintained (second orientation transfer process (bold arrows in the flow chart of FIG. 7)).

Next, with the board 100 maintained in the second orientation, residues which may remain in a small amount on the surface of the board 100 dried in the cleaning liquid drying process (S502) are removed using light, gas, plasma, or the like (dry cleaning process S504).

Next, the manufacturing system 400 monitors the progress of each process and detects whether or not there is a delay in the progress of the processes downstream of the dry cleaning process S504 (detection process S505). If the monitoring shows that there is a delay in the processes downstream of the dry cleaning process 5504 and it is necessary to temporarily store the board 100 (S505: Y), the board 100 in the second orientation is stored in the second orientation storage apparatus 406 (second orientation storage process S506).

Next, the board 100 is rotated from the second orientation to the first orientation (rotation) by the first rotation apparatus 407 between the wet cleaning process (S501) and the printing process (S508) (first rotation process S507).

Next, the raw material liquid for forming at least one of the light-emission contribution layers is applied to the printing surface 103 of the board 100 in the first orientation (printing process S508).

Note that in the present embodiment, the process which is downstream of the dry cleaning process S504 and is the first printing process is described as the printing process S508. However, in the case of forming a plurality of light-emission contribution layers through printing processes, each of the printing processes is referred to as the printing process S508.

Next, the raw material liquid printed on the board 100 in the printing process (S508) is dried by the drying apparatus 409 (drying process S509). For example, in the drying process (S509), the temperature of the board 100 is raised to a temperature higher than the atmospheric temperature by using a heater or the like.

Next, the board 100 on which the raw material liquid is printed in the printing process (S508) is rotated from the first orientation to the second orientation by the second reverse rotation apparatus 410 (second reverse rotation process S510).

Next, the board 100 rotated to the second orientation in the second reverse rotation process (S510) is heated with the second orientation maintained, at a temperature higher than the temperature in the drying process (S509) (baking process S511).

With the above-described manufacturing method, during a period after the wet cleaning process S501 and before the printing process S508, the board 100 is maintained in the second orientation in which the contaminant does not easily stick to the board 100. This makes it possible to inhibit, to the extent possible, the contaminant from becoming stuck to the printing surface 103 of the board 100 on which a light-emission contribution layer is to be formed.

### [Variation]

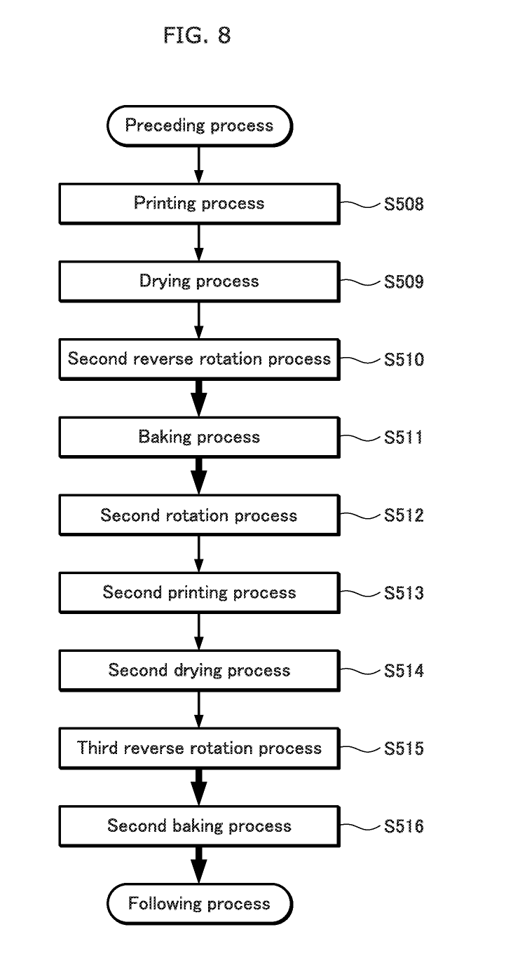

FIG. 8 is a flow chart illustrating the case where there are two or more printing processes.

As illustrated in FIG. 8, when the initial printing process S508, the drying process S509, the second reverse rotation process S510, and the baking process S511 are finished, a second rotation process S512 is performed to rotate the board 100 to the first orientation for forming another light-emission contribution layer.

Next, a second printing process S513 is performed on the board 100 in the first orientation to form another light-emission contribution layer.

Next, a second drying process S514 is performed for drying the printed raw material liquid. By doing so, another light-emission contribution layer is formed on the surface of the board 100.

The above state eliminates the possibility of, for example, the raw material liquid dripping even when the board 100 is rotated, and thus a third reverse rotation process S515 is performed.

By doing so, the board 100 can be maintained in an orientation in which the contaminant does not easily stick to the board 100. Then, a second baking process S516 is performed on the board 100 maintained in the second orientation.

In the case of repeating the printing process two or more times as above, it is possible to inhibit, to the extent possible, the possibility of the contaminant becoming stuck to the board 100, by performing the reverse rotation process after each printing process.

### Other Embodiments

As shown above, an embodiment and a variation have been described by way of example to illustrate the technique disclosed in the present application. However, the technique according to the present disclosure is not limited to these embodiment and variation, and is also applicable to other embodiments conceived by various modifications, permutations, additions, and omissions in the above-described embodiment and variation. Moreover, the structural elements described in Embodiment 1 and the variation may be combined to create a new embodiment.

For example, the organic EL display panel 300 in the above embodiment is included in a television. The organic EL display panel 300, however, may be used for equipment other than television. For example, the organic EL display panel 300 may be used for: a monitor apparatus that displays videos received from outside; digital signage used as advertising media; and a mobile terminal, a tablet terminal, and a table-type organic EL display panel 300 that receive a user operation via a touch panel.

As shown above, an embodiment has been described by way of example to illustrate the technique according to the present disclosure. The accompanying drawings and detailed description are provided for this purpose.

Thus, the structural elements set forth in the accompanying drawings and the detailed description include not only the structural elements essential to solve the problems but also structural elements unnecessary to solve the problems, for the purpose of illustrating the above technique by way of example. For this reason, those unnecessary structural elements should not be deemed essential due to the mere fact that they appear in the accompanying drawings and the detailed description.

The above-described embodiment illustrates the technique according to the present disclosure by way of example, and thus various modifications, permutations, additions, and omissions are possible in the scope of the appended claims and the equivalents thereof.

### INDUSTRIAL APPLICABILITY

The present disclosure relates to a method for manufacturing an organic EL display panel that displays images, characters, and videos, and a system for manufacturing the organic EL display panel. The present disclosure is applicable particularly to a large organic EL display panel. More specifically, the present disclosure is applicable to electronic devices such as a television, a monitor display, digital signage, a mobile terminal, a tablet terminal, and a table-type organic EL display panel.

### REFERENCE SIGNS LIST

100 board
101 bank
102 light-emitting pixel
103 printing surface
111 longitudinal bank
112 horizontal bank
300 organic EL display panel
399 television
400 manufacturing system
401 wet cleaning apparatus
402 cleaning liquid drying apparatus
403 first reverse rotation apparatus
404 dry cleaning apparatus
405 second orientation transfer apparatus
406 second orientation storage apparatus
407 first rotation apparatus
408 printing apparatus
409 drying apparatus
410 second reverse rotation apparatus
411 baking apparatus
481 chamber

1. A method for manufacturing an organic electroluminescent (EL) display panel through a printing process of applying, to a printing surface of a board in a first orientation, a raw material liquid for forming at least one of light-emission contribution layers including a light-emission layer, the printing surface being one surface of the board, the first orientation being an orientation of the board in which the printing surface faces upward and is held in a horizontal direction, the method comprising:
a wet cleaning process of cleaning the board using a liquid; and
a first rotation process of rotating the board from a second orientation to the first orientation after the wet cleaning process, the second orientation being an orientation of the board in which the printing surface is tilted at an angle with respect to the printing surface in the first orientation, the angle being selected from a range from 90 degrees to 270 degrees inclusive,
wherein the printing process is performed after the first rotation process.

2. The method for manufacturing an organic EL display panel according to claim 1, comprising:
a first reverse rotation process of rotating the board from the first orientation to the second orientation after the wet cleaning process; and
a dry cleaning process of dry cleaning the board rotated to the second orientation in the first reverse rotation process.

3. The method for manufacturing an organic EL display panel according to claim 1, comprising
a second orientation transfer process of transferring the board in the second orientation between the wet cleaning process and the printing process.

4. The method for manufacturing an organic EL display panel according to claim 1, comprising
a second orientation storage process of storing the board in the second orientation between the wet cleaning process and the printing process, the board comprising a plurality of boards.

5. The method for manufacturing an organic EL display panel according to claim 1, comprising:
a drying process of drying the raw material liquid applied in the printing process;
a second reverse rotation process of rotating the board from the first orientation to the second orientation; and
a baking process of processing the board rotated to the second orientation in the second reverse rotation process, at a temperature higher than a temperature in the drying process.

6. A system for manufacturing an organic electroluminescent (EL) display panel, the system comprising:
a printing apparatus that applies, to a printing surface of a board in a first orientation, a raw material liquid for forming at least one of light-emission contribution layers including a light-emission layer, the printing surface being one surface of the board, the first orientation being an orientation of the board in which the printing surface faces upward and is held in a horizontal direction;
a wet cleaning apparatus that cleans the board using a liquid before the board is transferred to the printing apparatus; and
a first rotation apparatus that is positioned between the wet cleaning process and the printing apparatus in a production line and rotates the board from a second orientation to the first orientation, the second orientation being an orientation of the board in which the printing surface is tilted at an angle with respect to the printing surface in the first orientation, the angle being selected from a range from 90 degrees to 270 degrees inclusive.
